(19) United States
(12) Patent Application Publication
(10) Pub. No.: US 2009/0294792 A1
(43) Pub. Date: Dec. 3, 2009

(54) CARD TYPE MEMORY PACKAGE

(75) Inventors: Kuo-Yuan Lee, Kaohsiung (TW); Ke-Wen Lu, Kaohsiung (TW); Ta-Wei Kuo, Kaohsiung (TW); Wen-Chun Chiu, Kaohsiung (TW); Pi-Wei Hsu, Kaohsiung (TW)

Correspondence Address: Muncy, Geissler, Olds & Lowe, PLLC, P.O. BOX 1364, FAIRFAX, VA, 22038-1364, US

(73) Assignee: Walton Advanced Engineering, Inc.

(21) Appl. No.: 12/130,518

(22) Filed: May 30, 2008

(51) Int. Cl. H01L 33/00

(52) U.S. Cl. 257/99; 257/E33.056

(57) ABSTRACT

A card-type memory package is revealed, primarily comprising a substrate, a plurality of gold fingers, at least a memory chip, an LED chip, and an encapsulant. The memory chip and the LED chip are disposed on an encapsulated surface of the substrate with the LED chip adjacent to a rear side of the substrate. The gold fingers are attached to the substrate adjacent to a front side of the substrate. The encapsulant is formed on the encapsulated surface to encapsulate the memory chip and the LED chip with the gold fingers exposed. Therefore, the card-type memory package has the LED indication of reading and writing information with simplified assembling processes.

### FIELD OF THE INVENTION

The present invention relates to semiconductor devices, especially to a card-type memory package.

### BACKGROUND OF THE INVENTION

There are many types of small memory devices such as USB flash drives, SD cards, mini SD, Micro SD cards (or TransFlash), MS cards, CF cards, MMC, etc. for reading and writing information in electronic products such as computers, digital cameras, cellular phones, etc. Since the demand of memory capacities from end users keeps increasing, USB flash drives become one of the most common portable memory devices, however, the manufacture and assembly processes are rather complicated. At least a memory package is disposed on a module board with a plurality of gold fingers. Then, the module board is assembled with a USB metal plug to make the gold fingers inside and finally assembled in a plastic casing capped with a back cover to prevent the module board dropping from the plastic casing. A portable memory device with a complete electrical function is ready for use.

As shown in FIG. 1, a conventional USB flash drive 100 comprises a module board 110, a plurality of gold fingers 120, at least a memory package 130, a plastic case 140, a USB metal plug 150, and a back cover 160. The module board 110 has a top surface 111, a front side 112, and a corresponding rear side 113 where the gold fingers 120 are disposed on the top surface 111 adjacent to the front side 112. The memory package 130 is disposed on the top surface 111 of the module board 110 where the memory package 130 includes a memory chip encapsulated by a molding compound. The module board 110 is assembled and fixed inside the plastic casing 140 to protect the module board 110 where the plastic casing 140 has an extended insulator 141 supporting the gold fingers 120. The USB metal plug 150 is connected to the extended insulator 141 of the plastic casing 140, i.e., the front side 112 of the module board 110 to form a USB connector. The USB flash drive 100 can be plugged into a USB socket of a computer or other electronic devices to read and write information. The back cover 160 is disposed on the backend of the plastic casing 140, i.e., the rear side 113 of the module board 110 to prevent the module board 110 dropping out from the backend of the plastic casing 140. However, a USB flash drive 100 needs many complicated processing and assembling steps with longer cycle time leading to lower productivity.

### SUMMARY OF THE INVENTION

The main purpose of the present invention is to provide a card-type memory package, comprising an LED chip encapsulated with the memory chip in the same encapsulant to indicate reading and writing functions where the LED chip is disposed by Chip-On-Board (COB) to simplify manufacture processes to reduce cycle times and to increase productivity.

The second purpose of the present invention is to provide a card-type memory package directly assembled with a USB metal plug to form a USB flash drive to simplify assembly processes and cycle times.

The third purpose of the present invention is to provide a card-type memory package with one single wire-bonding process to complete electrical connections of memory chips and LED chips.

According to the present invention, a card-type memory package is revealed, primarily comprising a substrate, a plurality of gold fingers, at least a memory chip, an LED chip, and an encapsulant. The substrate has an encapsulated surface, an external surface, a front side, and a corresponding rear side. The gold fingers are attached to the substrate adjacent to the front side. The memory chip and the LED chip are disposed on the encapsulated surface. The encapsulant is formed on the encapsulated surface to encapsulate the memory chip and the LED chip at the same time with the gold fingers exposed from the encapsulant. The LED chip is adjacent to the rear side of the substrate in a manner to light up from the encapsulant.

### DESCRIPTION OF THE DRAWINGS

FIG. 1 shows a three-dimensional exploded view of a conventional USB flash drive.

FIG. 2 shows a three-dimensional view of a card-type memory package according to the first embodiment of the present invention.

FIG. 3 shows a cross-sectional view of a card-type memory package according to the first embodiment of the present invention.

FIG. 4 shows a top view of a substrate strip including a plurality of substrates of a card-type memory package according to the first embodiment of the present invention.

FIG. 5 shows a cross-sectional view of the card-type memory package before encapsulation according to the first embodiment of the present invention.

FIG. 6 shows a cross-sectional view of a card-type memory package according to the second embodiment of the present invention.

FIG. 7 shows a cross-sectional view of a card-type memory package before encapsulation according to the second embodiment of the present invention.

FIG. 8 shows a three-dimensional view of the marking surface of a card-type memory package according to the second embodiment of the present invention.

FIG. 9 shows a three-dimensional view of the substrate surface of a card-type memory package according to the second embodiment of the present invention.

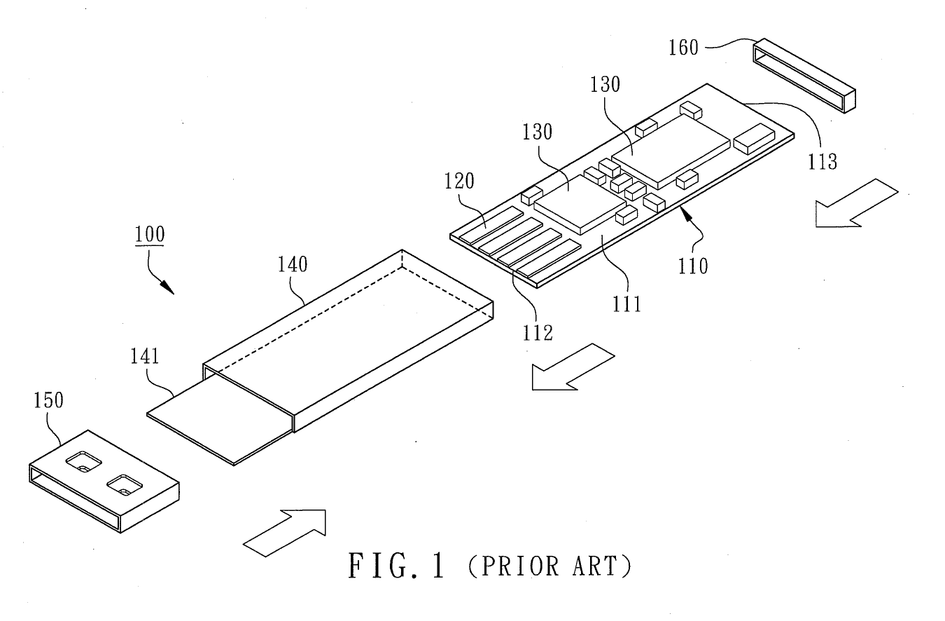

### DETAIL DESCRIPTION OF THE INVENTION

Please refer to the attached drawings, the present invention will be described by means of embodiments below.

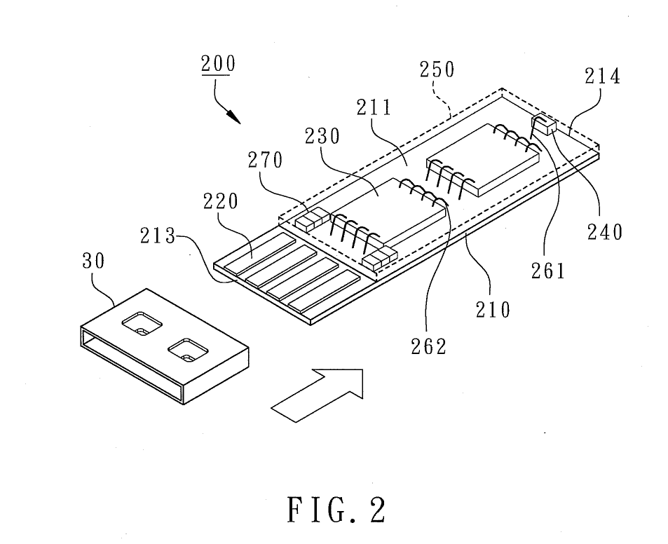

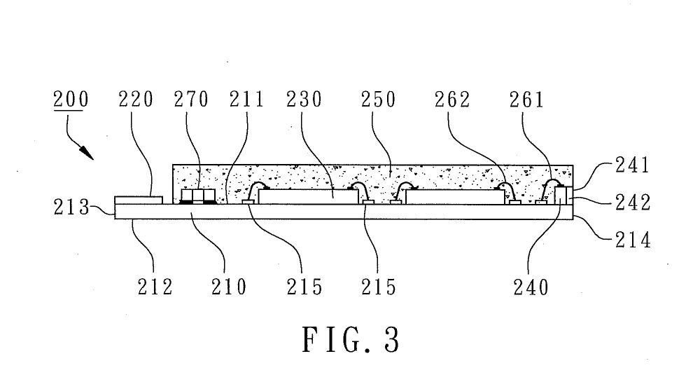

The first embodiment of a card-type memory package according to the present invention is illustrated in the three-dimensional view of FIG. 2 and the cross-sectional view of FIG. 3. The card-type memory package 200 primarily comprises a substrate 210, a plurality of gold fingers 220, at least a memory chip 230, an LED chip 240, and an encapsulant 250. The substrate 210 has an encapsulated surface 211, an external surface 212, a front side 213, and a rear side 214 where the memory chip 230 and the LED chip 240 are disposed on the encapsulated surface 211 and are encapsulated by the encapsulant 250. The so-called “encapsulated surface” means the surface of the substrate encapsulated by the encapsulant 250. A plurality of internal bonding pads 215 are disposed on the encapsulated surface 211 of the substrate 210.

As shown in FIG. 3, the gold fingers 220 are attached to the substrate 210 toward the front side 213 as the external electrical connections of the card-type memory package 200. In the present embodiment, the gold fingers 220 are disposed on an area of the encapsulated surface 211 not encapsulated by the encapsulant 250.

The memory chip 230 is disposed on the encapsulated surface 211 of the substrate 210 where the memory chip 230 can be a flash memory chip or other non-volatile memory chip. As shown in FIG. 3, the LED chip 240 is also disposed on the encapsulated surface 211 of the substrate 210 adjacent to the rear side 214. In the present embodiment, the memory chip 230 is attached to the encapsulated surface 211 of the substrate 210 by non-conductive adhesive such as epoxy or PI tape and the LED chip 240 by conductive adhesive or solder.

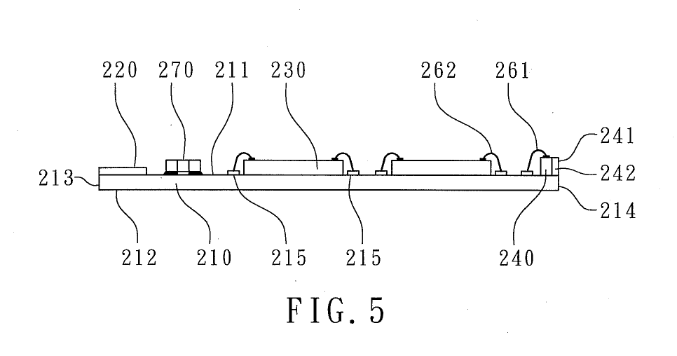

In the present embodiment, the LED chip 240 has a glowing surface 241 exposed from a side of the encapsulant 250 aligned with the rear side 214 of the substrate 210 (as shown in FIG. 3). Preferably, the LED chip 240 includes a transparent layer 242 disposed on the glowing surface 241 for radiating the light so that the encapsulant 250 can be made of non-transparent material, for example, the encapsulant 250 is black. As shown in FIG. 5, the card-type memory package 200 further comprises at least a first bonding wire 261 and a plurality of second bonding wires 262 formed by wire-bonding technology. The first bonding wire 261 electrically connects the LED chip 240 to one of the internal bonding pads 215 of the substrate 210. The memory chip 230 is electrically connected to the internal bonding pads 215 of the substrate 210 by the second bonding wires 262. Therefore, the electrical connections of the memory chip 230 and the LED chip 240 can be done within the same wire bonding processes.

Preferably, the card-type memory package 200 further comprises at least a passive component 270 and at least a control chip (not shown in the figures) disposed on the encapsulated surface 211 of the substrate 210 and encapsulated by the encapsulant 250. In the present embodiment, the passive component 270 is a chip-type SMD (surface mount device).

As shown in FIG. 2 and FIG. 3, the encapsulant 250 is formed on the encapsulated surface 211 of the substrate 210 to encapsulate the memory chip 230 and the LED chip 240 at the same time with the gold fingers 220 exposed from the encapsulant 250. Therefore, only one encapsulation process is needed to complete a card-type memory package 200 with full electrical functions. The encapsulant 250 is formed by transfer molding, printing, or dispensing to continuously encapsulate the encapsulated surface 211 of the substrate 210 including the memory chip 230 and the LED chip 240. In the present embodiment, the encapsulant 250 is an opaque resin, however, the light radiated from the LED chip 240 can glow through the transparent layer 242. In the present embodiment, the encapsulant 250 forms the brick body of a USB flash drive where “USB” stands for “Universal Serial Bus” which is an international standard for connectors. As shown in FIG. 2, when the encapsulant 250 forms the brick body of a USB flash drive, a USB metal plug 30 can be joined to the encapsulant 250 to cover the front side 213 of the substrate 210 where the gold fingers 220 are hidden inside the USB metal plug 30 to form a USB male connector to insert into a USB socket of an electronic device such as a desktop computer or a laptop computer for reading and writing information. The USB metal plug 30 is made of conductive metals such as stainless steel.

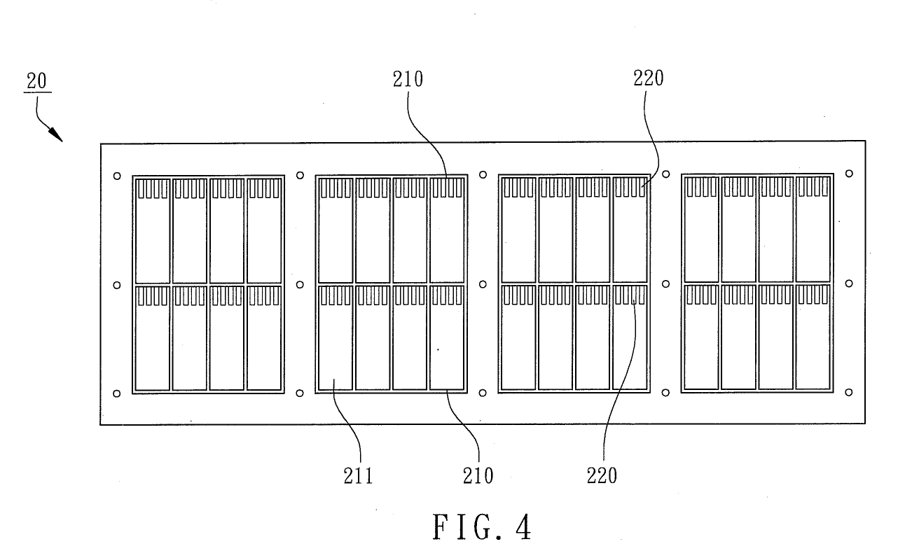

During the manufacturing processes of the above mentioned card-type memory package 200, as shown in FIG. 4, a plurality of substrate 210 are disposed in an array and integrally connected in a substrate strip 20. As shown in FIG. 5, a memory chip 230, an LED chip 240 and other components such as passive components and control chip are disposed on the encapsulated surface 211 of each individual substrate 210. A wire-bonding process is performed to form the first bonding wires 261, and the second bonding wires 262. As shown in FIG. 3, during encapsulation processes, the encapsulant 250 on the encapsulated surfaces 211 encapsulates the memory chip 230, the LED chip 240, the first bonding wires 261, and the second bonding wires 262 at the same time or even encapsulates the passive component 270 and the control chip. The encapsulant 250 covers a plurality of substrates 210 of the substrate strip 20. After cutting the scribe lines between the substrates 210 via a laser or via a sawing tool, a plurality of card-type memory packages 200 are singulated from the substrate strip 20. Accordingly, the manufacturing processes are simplified and the cycle time is reduced and the productivity is increased. When the card-type memory packages 200 works, the encapsulated LED chip 240 lights up from the encapsulant 250 at the rear side 214. Therefore, the reading and writing indication light can be integrated into the COB packaging processes to greatly reduce assembling steps. In the present embodiment, as shown in FIG. 2 again, just by joining the USB metal plug 30 to the encapsulant 250 of the card-type memory package 200, a tiny USB flash device is manufactured. The assembling processes are effectively simplified.

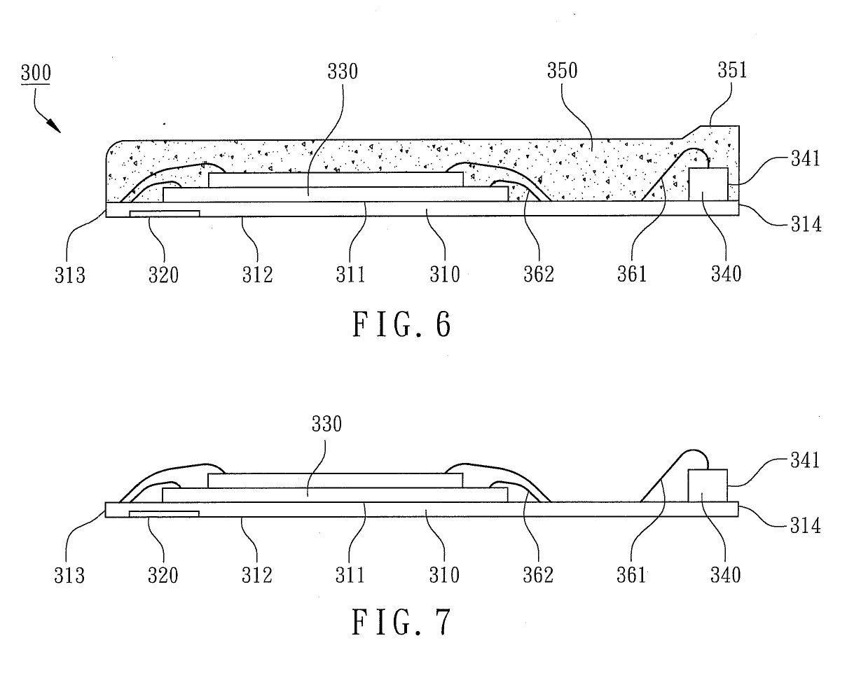

In the second embodiment of the present invention, another card-type memory package 300 is illustrated in the cross-sectional view of FIG. 6. The card-type memory package 300 primarily comprises a substrate 310, a plurality of gold fingers 320, at least a memory chip 330, an LED chip 340, and an encapsulant 350. The substrate 310 has an encapsulated surface 311, an external surface 312, a front side 313, and a rear side 314. The gold fingers 320 are attached to the substrate 310 toward the front side 313. In the present embodiment, the gold fingers 320 are disposed on the external surface 312 of the substrate 310 adjacent to the front side 313, and the encapsulant 350 completely covers the encapsulated surface 311. As shown in FIG. 7, before encapsulation, the memory chip 330 and the LED chip 340 are disposed on the encapsulated surface 311 of the substrate 310 where the LED chip 340 is disposed adjacent to the rear side 314 of the substrate 310. The LED chip 340 has a glowing surface 341 toward the rear side 314. As shown in FIG. 7, in the present embodiment, the LED chip 340 is electrically connected to the substrate 310 by a first bonding wire 361 and the memory chip 330 is electrically connected to the substrate 310 by a plurality of second bonding wires 362.

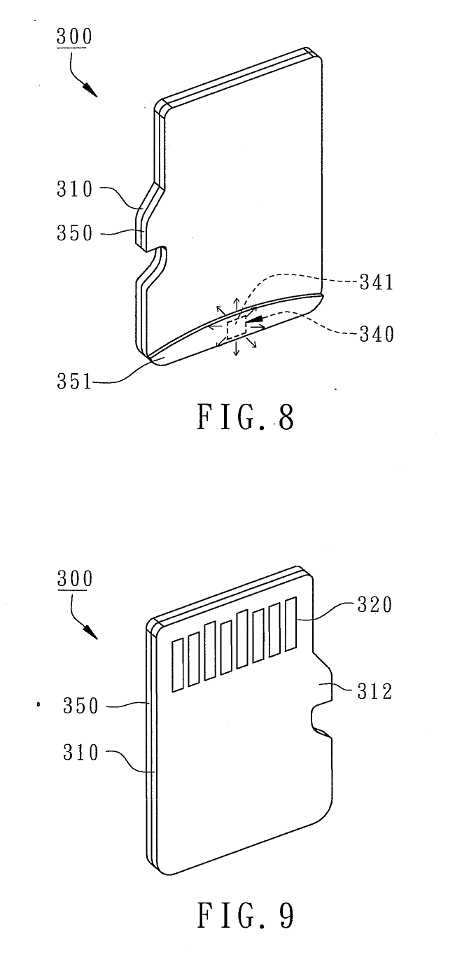

As shown in FIG. 6 again, the encapsulant 350 is formed on the encapsulated surface 311 of the substrate 310 to encapsulate the memory chip 330 and the LED chip 340 at the same time with the gold fingers 320 exposed from the encapsulant 350. In the present embodiment, the encapsulant 250 can be transparent or translucent and the LED chip 340 is adjacent to the rear side 314 in a manner that the light can be radiated from the LED chip 340, as shown in FIG. 8. The encapsulant 350 can further mix with different dyes such as yellow or blue to change the colors of the translucent resin materials. In the present embodiment, the encapsulant 350 forms the major body of the card-type memory package 300, for example, a card body of a memory card. As shown in FIG. 8 and FIG. 9, the memory card formed by the encapsulant 350 is a Micro SD card. As shown in FIG. 6 and FIG. 8, the encapsulant 350 has a thickened portion 351 at the rear side 314 for pulling out the memory card by fingers. Preferably, as shown in FIG. 6 again, the first bonding wire 361 and the LED chip 340 are encapsulated in the thickened portion 351 of the encapsulant 350 to accommodate a larger LED chip and a bonding wire having a higher loop height. However, without any limitations, the memory cards formed by the encapsulant 350 can also be other memory cards such as SD cards, mini SD cards, MS cards, CF cards, MMC, etc.

The above description of embodiments of this invention is intended to be illustrative and not limiting. Other embodiments of this invention will be obvious to those skilled in the art in view of the above disclosure.

What is claimed is:

1. A card-type memory package primarily comprising:
a substrate having an encapsulated surface, an external surface, a front side, and a rear side;
a plurality of gold fingers attached to the substrate adjacent to the front side;
at least a memory chip disposed on the encapsulated surface;
an LED chip disposed on the encapsulated surface; and
an encapsulant formed on the encapsulated surface to encapsulate the memory chip and the LED chip with the gold fingers exposed from the encapsulant;
wherein the encapsulated LED chip is adjacent to the rear side in a manner to light up from the encapsulant.

2. The card-type memory package as claimed in claim 1, wherein the LED chip has a glowing surface exposed from a side of the encapsulant aligned with the rear side of the substrate.

3. The card-type memory package as claimed in claim 2, wherein the LED chip includes a transparent layer on the glowing surface of the LED chip.

4. The card-type memory package as claimed in claim 3, wherein the encapsulant is opaque.

5. The card-type memory package as claimed in claim 1, wherein the encapsulant is transparent or translucent so that the light of the LED chip radiates through the encapsulant.

6. The card-type memory package as claimed in claim 1, further comprising at least a first bonding wire electrically connecting the LED chip to the substrate.

7. The card-type memory package as claimed in claim 6, further comprising a plurality of second bonding wires electrically connecting the memory chip to the substrate.

8. The card-type memory package as claimed in claim 6, wherein the encapsulant has a thickened portion in which the first bonding wire and the LED chip are encapsulated.

9. The card-type memory package as claimed in claim 1, wherein the gold fingers are disposed on an area of the encapsulated surface not encapsulated by the encapsulant.

10. The card-type memory package as claimed in claim 1, wherein the gold fingers are disposed on the external surface of the substrate, wherein the encapsulant completely covers the encapsulated surface.

11. The card-type memory package as claimed in claim 1, wherein the encapsulant forms a brick body of the USB flash drive.

12. The card-type memory package as claimed in claim 11, wherein the encapsulant is opaque.

13. The card-type memory package as claimed in claim 1, wherein the encapsulant forms a card body of a memory card.

14. The card-type memory package as claimed in claim 13, wherein the encapsulant is transparent or translucent.

15. The card-type memory package as claimed in claim 13, wherein the memory card is a micro SD card.

16. The card-type memory package as claimed in claim 1, further comprising at least a passive component disposed on the encapsulated surface of the substrate and encapsulated by the encapsulant.

17. The card-type memory package as claimed in claim 16, wherein the passive component is a chip-type SMD.

18. The card-type memory package as claimed in claim 1, further comprising a USB metal plug joined to the encapsulant.
